(19) United States
(12) Patent Application Publication
(10) Pub. No.: US 2025/0062220 A1
(43) Pub. Date: Feb. 20, 2025

(54) Vertically Stacked Capacitors

(71) Applicant: Ampleon Netherlands B.V., Nijmegen (NL)

(72) Inventors: Daniel Maassen, Nijmegen (NL); Bart Van Velzen, Nijmegen (NL)

(21) Appl. No.: 18/805,671

(22) Filed: Aug. 15, 2024

(30) Foreign Application Priority Data
Aug. 15, 2023 (NL) 2035611

(51) Int. Cl. H01L 23/522; H01L 29/94; H03F 3/195

(52) U.S. Cl. CPC H01L 23/5223; H01L 28/91; H01L 29/945; H03F 3/195

(57) ABSTRACT

Example embodiments relate to vertically stacked capacitors. One capacitor assembly includes a vertical stacking of a first capacitor and a second capacitor on a substrate. The first capacitor includes a first terminal and a second terminal. The second terminal is formed by a first conductive layer that includes stress relief openings. The second capacitor includes a first terminal and a second terminal. The second terminal of the first capacitor lies below the first terminal of the first capacitor. The second terminal of the second capacitor lies below the first terminal of the second capacitor. The second capacitor lies below the first capacitor. The capacitor assembly further includes a ground layer. The second terminal of the second capacitor is electrically connected to the ground layer and to the first conductive layer. The ground layer includes stress relief openings. The ground layer is configured to be electrically grounded during operation.

### CROSS-REFERENCE TO RELATED APPLICATIONS

The present application is a non-provisional patent application claiming priority to Netherlands Patent Application No. NL 2035611, filed Aug. 15, 2023, the contents of which are hereby incorporated by reference.

### FIELD OF THE DISCLOSURE

The present disclosure provides a capacitor assembly comprising a vertical stacking of a first capacitor and a second capacitor on a substrate. The present disclosure further relates to an amplifier comprising such a capacitor assembly.

### BACKGROUND

Contemporary radiofrequency, RF, amplifiers used in telecommunications systems such as base stations are subjected to stringent requirements regarding linearity of the system. Non-linear behavior may result in distortion of signals. RF amplifiers typically comprise a power transistor such as a laterally diffused metal-oxide-semiconductor, LDMOS, transistor, or a Gallium Nitride field-effect transistor.

To improve the linearity of the RF amplifier, it is important to control the impedance presented at the output of the power transistor in the so-called video bandwidth. In the art, it is known to present an RF short in the video bandwidth, which is typically realized using a capacitor with a relatively large capacitance in the range between 0.1 and 10 nF. At the same time, a capacitor having a smaller capacitance in the range between 5 and 500 pF is connected at the output of the power transistor to obtain impedance matching.

To obtain a compact configuration of the RF amplifier it is preferred to realize as many components as possible within a given footprint without degrading performance. Furthermore, contemporary technologies used for manufacturing the abovementioned large and small capacitances allow for a vertical stacking of these capacitors.

US2023223332A1 discloses, in its abstract, first and second wells that are formed in a semiconductor substrate. First and second trenches in the first second wells, respectively, each extend vertically and include a central conductor insulated by a first insulating layer. A second insulating layer is formed on a top surface of the semiconductor substrate. The second insulating layer is selectively thinned over the second trench. A polysilicon layer is deposited on the second insulating layer and then lithographically patterned to form: a first polysilicon portion over the first well that is electrically connected to the central conductor of the first trench to form a first capacitor plate, a second capacitor plate formed by the first well; and a second polysilicon portion over the second well forming a floating gate electrode of a floating gate transistor of a memory cell having an access transistor whose control gate is formed by the central conductor of the second trench.

CN115631688A discloses a display panel and a preparation method thereof, and an electronic device.

The Applicant has found that known methods for vertically stacking capacitors introduce an unwanted coupling between these capacitors.

### SUMMARY

Example embodiments provide a capacitor assembly comprising a vertical stacking of a first capacitor and a second capacitor on a substrate that reduces the coupling between these capacitors.

In some embodiments, the first capacitor comprises a first terminal and a second grounded terminal, wherein the second grounded terminal is formed by a first conductive layer that comprises relief openings. The second capacitor comprises a first terminal and a second grounded terminal.

Relative to a surface of the substrate, the second grounded terminal of the first capacitor lies below the first terminal of the first capacitor, and the second grounded terminal of the second capacitor lies below the first terminal of the second capacitor. Furthermore, the second capacitor lies below the first capacitor.

In some embodiments, the capacitor assembly further comprises a ground layer arranged in between the first conductive layer and the first terminal of the second capacitor, wherein the second grounded terminal of the second capacitor is electrically connected, through one or more vias to the ground layer and to the first conductive layer, wherein the ground layer comprises relief openings that are laterally separated from the relief openings of the first conductive layer.

In manufacturing technologies, such as semiconductor technologies, the use of large metal planes is typically prohibited. To comply with design rules, the planes should be provided with openings in order to 5 um. Within the context of the present disclosure, these openings are referred to as relief openings.

It should be noted that within the context of the present disclosure, openings in different vertical layers of the capacitor assembly are said to be laterally separated from each other when their respective normal projections onto a surface of the substrate are not overlapping.

By using the configuration of the capacitor assembly according to the present disclosure, capacitive coupling between the first terminal of the first capacitor and the first terminal of the second capacitor can be prevented and/or limited while at the same time ensuring a high manufacturability and reliability of the capacitor assembly. More in particular, a normal projection of the second grounded terminal of the first capacitor on the substrate combined with a normal projection of the ground layer on the substrate yields a plane that is entirely ‘filled’ with conductive material. Accordingly, electromagnetic coupling between the first and second capacitors is prevented or at least limited.

The first terminal of the first capacitor can be formed by a capacitor top metal layer. The capacitor top metal layer may comprise relief openings, wherein the relief openings in the ground layer are laterally separated from the relief openings of the capacitor top metal layer. In this manner, any field lines from the capacitor top metal layer extending perpendicular to the capacitor top metal layer and down to the substrate would ‘see’ the ground plane and would therefore not result in electromagnetic coupling between the first and second capacitors or hardly so.

The capacitor top metal layer may comprise a plurality of stripes that are arranged in parallel and that are laterally separated by the relief openings of the capacitor top metal layer. The relief openings in the ground layer are preferably arranged underneath the stripes, preferably entirely.

The capacitor assembly may further comprise a second conductive layer separated from the capacitor top metal layer by a dielectric layer, wherein the second conductive layer is electrically connected to the capacitor top metal layer through one or more vias through the dielectric layer. The second conductive layer may comprise relief openings that are laterally separated from the relief openings in the capacitor top metal layer. The second conductive layer can typically be made using thicker metal layers than the capacitor top metal layer, thereby reducing the resistance of the first capacitor.

The capacitor assembly may further comprise a third conductive layer separated from the second conductive layer by a dielectric layer, wherein the third conductive layer is electrically connected to the second conductive layer through one or more vias through the dielectric layer. The third conductive layer may comprise relief openings that are laterally aligned with the relief openings in the first conductive layer.

The capacitor assembly may further comprise a fourth conductive layer separated from the ground layer by a dielectric layer and electrically connected to and/or forming the first terminal of the second capacitor, wherein the fourth conductive layer comprises relief openings that are laterally separated from the relief openings in the ground plane. More in particular, the relief openings in the fourth conductive layer can be formed around the vias that are used for connecting the second grounded terminal of the second capacitor to the ground plane.

The first terminal of the second capacitor can be formed by a fifth conductive layer that is separated from the fourth conductive layer by a dielectric layer, wherein the fourth conductive layer is electrically connected to the fifth conductive layer through one or more vias through the dielectric layer. For example, the fifth conductive layer may comprise a polysilicon layer and the fourth conductive layer a metal layer having a reduced sheet resistance when compared to the polysilicon layer.

The capacitor assembly may comprise a plurality of identical and adjacently arranged unit cells, each unit cell comprising a first capacitor unit cell, a second capacitor unit cell, and a ground plane segment. Typically, when designing a capacitor assembly using computer-aided design, CAD, tools, a capacitor assembly can be provided in the form of a scalable component, wherein a given capacitance value for the first and/or second capacitor can be obtained by selecting a number of unit cells to be used as well as the dimensions of such unit cell.

For such a unit cell, the relief openings of the ground plane are each preferably arranged in a respective center region of a unit cell among the plurality of unit cells.

The relief openings of the fourth conductive layer are preferably each arranged at a respective corner of a respective second capacitor unit cell. Similarly, the relief openings of the first conductive layer are each preferably arranged at a respective edge of a respective first capacitor unit cell. The relief openings of the second conductive layer are preferably each arranged in a center position of a respective first capacitor unit cell. The relief openings of the third conductive layer are preferably each arranged at a respective edge of a respective first capacitor unit cell.

The first conductive layer, the second conductive layer, the third conductive layer, the fourth conductive layer, the ground layer, and the capacitor top metal layer may each comprise one or more metals. Typically, these metals are part of a so-called metal stack. The fifth conductive layer may comprise a polysilicon layer. Alternatively, the fifth conductive layer may also comprise one or more metals.

The substrate can be a semiconductor substrate, such as a Silicon substrate, or a Gallium Nitride substrate. It should be noted that a Gallium Nitride substrate may comprise Gallium Nitride, GaN, and/or Gallium Nitride based layers, such as AlN or AlGaN layers, that have been grown on a substrate that may differ from GaN. For example, GaN substrates are known in which a Silicon, Silicon Carbide, or Sapphire substate is used on which the GaN or GaN based layers were grown.

The first capacitor can be a metal-insulator-metal capacitor, and/or the second capacitor can be a high-density capacitor. In case the second capacitor is a high-density capacitor, it can be embodied as a deep trench capacitor that comprises a plurality of trenches in the semiconductor substrate of which an inner wall is covered by a first insulating layer, wherein the fifth conductive layer covers the first insulating layer, and wherein the semiconductor substrate comprises one or more doped regions that form the second grounded terminal of the second capacitor. Furthermore, the metal-insulator-capacitor may comprise a second insulating layer arranged in between the capacitor top metal layer and the first conductive layer. This insulating layer typically comprises silicon oxide, silicon oxynitride, or silicon nitride.

According to a second aspect of the present disclosure, an amplifier is provided that comprises a field-effect transistor, FET, having an output capacitance, and the abovementioned capacitor assembly. The amplifier further comprises a shunt network connected to a drain of the FET that comprises a series connection of a first inductor and the first capacitor of the capacitor assembly, wherein the first inductor is connected to the drain of the FET, and wherein the first terminal of the first capacitor of the capacitor assembly is connected to the first inductor.

The shunt network further comprises the second capacitor of the capacitor assembly connected in series with a second inductor, wherein the second inductor is connected in between the first terminal of the first capacitor of the capacitor assembly and the second capacitor of the capacitor assembly, wherein the second capacitor of the capacitor assembly has its first terminal connected to the second inductor. As an example, the FET may comprise a silicon based laterally diffused metal-oxide-semiconductor, LDMOS, transistor. In this case, the insulating layer of the deep trench capacitor can be formed by a gate oxide layer of the LDMOS transistor.

### BRIEF DESCRIPTION OF THE DRAWINGS

Next, example embodiments will be described referring to the appended drawings, wherein identical or similar components will be referred to using the same reference signs.

FIG. 1 illustrates a cross section of a capacitor assembly, according to example embodiments.

FIG. 2 illustrates more details regarding the second capacitor of the capacitor assembly of FIG. 1, according to example embodiments.

FIG. 3 illustrates various layers of a unit cell for making the capacitor assembly of FIG. 1 in top view, according to example embodiments.

FIG. 4 illustrates how multiple unit cells can be combined for forming a capacitor assembly, according to example embodiments.

FIG. 5 illustrates an amplifier comprising the capacitor assembly, according to example embodiments.

### DETAILED DESCRIPTION

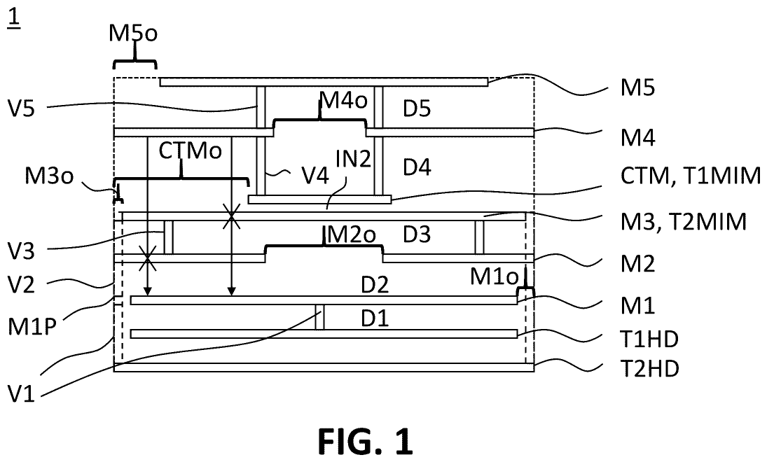

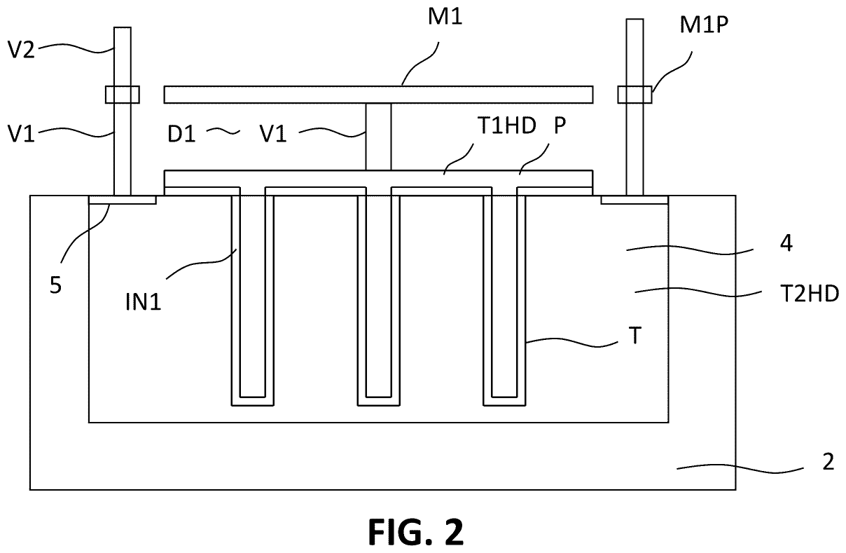

FIG. 1 illustrates a cross section of an embodiment of a capacitor assembly according to the present disclosure. More details on the second capacitor used in this assembly are provided in FIG. 2.

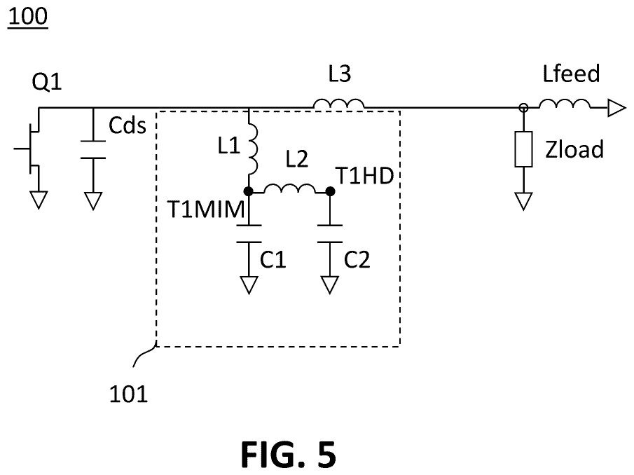

Capacitor assembly 1 is realized on a Silicon substrate 2. The semiconductor technology used for making capacitor assembly 1 is an LDMOS process. As shown in FIG. 5, according to the present disclosure, capacitor assembly 1 can be advantageously combined with an LDMOS transistor.

The abovementioned technology comprises several conductive layers that are described in the table below:

| Layer name | Layer thickness | | Layer material |
|---|---|---|---|
| M1 | 400-800 | nm | Aluminum |
| M2 | 400-800 | nm | Aluminum |
| M3 | 400-800 | nm | Aluminum |
| M4 | 1500-2500 | nm | Aluminum |
| M5 | 2500-3500 | nm | Aluminum |
| CTM | 100-200 | nm | TiN |
| P | 500-800 | nm | Poly-Silicon |

Now referring to FIG. 2, the second capacitor is formed as a deep trench capacitor, DTC. It comprises a plurality of trenches T that have been formed in semiconductor substrate 2, typically using dry-etching techniques. The inside walls of trenches T are covered by a first insulation layer IN1. In this case, IN1 is a silicon-oxide-silicon-nitride-silicon-oxide stack having a thickness between 100 and 200 nm.

On top of layer IN1, a first terminal T1HD is arranged that is made using a Polysilicon layer P. As the sheet resistance of Polysilicon is relatively high, a metal layer M1 is used. This layer is separated from layer P by a dielectric layer D1, which in this case is a silicon oxide layer having a thickness between 1000 and 2000 nm. Electrical connection between first terminal T1HD formed in layer P and the metal structures formed in layer M1 is realized using vias V1.

A second terminal T2HD of the deep trench capacitor is formed by doped regions 4 in semiconductor substrate 2. To enable an ohmic contact to doped regions 4, a highly-doped n-type contact region 5 is formed in semiconductor substrate 2. Typically, a contact metal layer (not shown) is arranged on contact region 5 for making the Ohmic contact. This contact metal layer is then connected to a patch MIP formed in layer M1 using a via V1. Patch MIP is in turn connected to the ground plane realized using layer M2 using a via V2, wherein the ground plane is connected to second terminal T2MIM of the first capacitor realized in metal layer M3 using a via V3. As illustrated in FIG. 1, some of the vias V1, V2, V3 can be stacked to form a pillar connecting T2HD to T2MIM.

Now referring to FIG. 1, the first capacitor is a metal-insulator-metal capacitor, MIMCAP, in which a second insulating layer IN2 comprising Silicon-nitride and having a thickness between 200 and 300 nm is arranged in between a first electrode TIMIM made in a capacitor top metal, CTM, layer, and a second electrode T2MIM made in metal layer M3. Second electrode T2MIM is connected to the ground plane formed in metal layer M2.

Hereinafter, reference signs may refer to a particular layer, e.g. metal layer M2, or may refer to the structures formed in that layer. For example, the first capacitor is formed by second insulating layer IN2 arranged between CTM and M2.

Second electrode T2MIM is connected to ground plane M2 using vias V3. Furthermore, metal layers M1 and M2 are separated by dielectric layer D2, which is a layer made of Silicon-oxide with a thickness in between 700 and 1100 nm. In addition, metal layers M2 and M3 are separated by dielectric layer D3, which is a layer made of Silicon-oxide with a thickness in between 700 and 1100 nm. Electrical connection between metal layers M2 and M3 is realized using vias V3.

As the sheet resistance of the CTM layer is relatively high, metal layers M4 and M5 are used. Here, the CTM layer and metal layer M4 are separated by dielectric layer D4, which is a layer made of Silicon-oxide with a thickness of between 1000 and 1400 nm, and metal layers M4 and M5 are separated by dielectric layer D5, which is a layer made of Silicon-oxide with a thickness of between 1000 and 1300 nm. Connection between metal layer M5 and metal layer M4 is realized using vias V5, whereas vias V4 are used for connecting metal layer M4 and the CTM layer.

In FIG. 1, accolades “{” are used to indicate openings in the various layers. For example, M1o, M2o, M3o, M4o, and M5o, are used to indicate openings in metal layers M1, M2, M3, M4, and M5, respectively. These openings are required for stress relief.

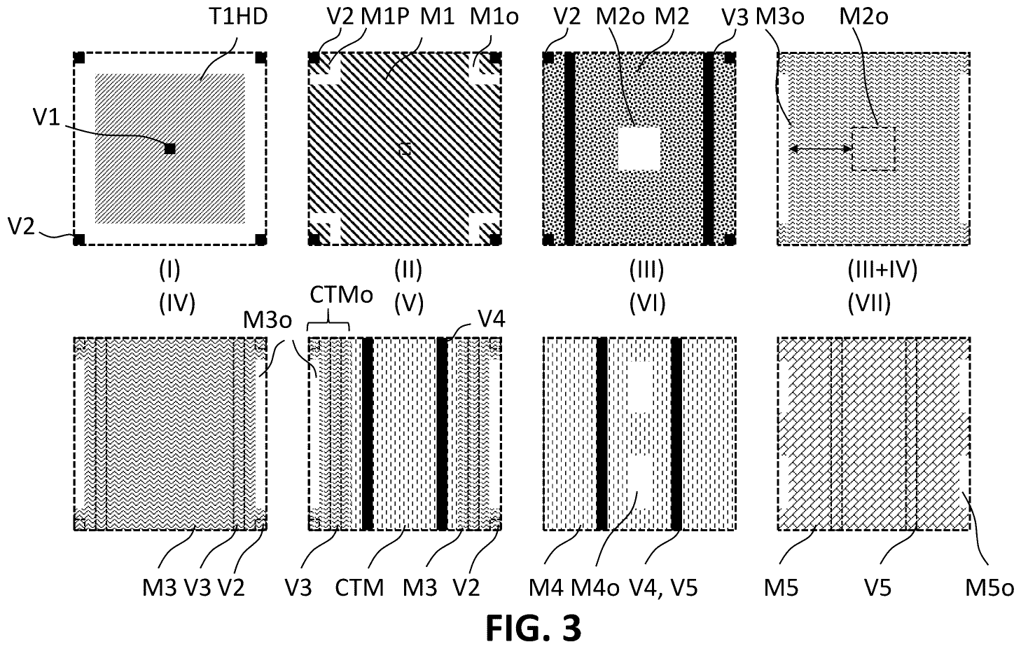

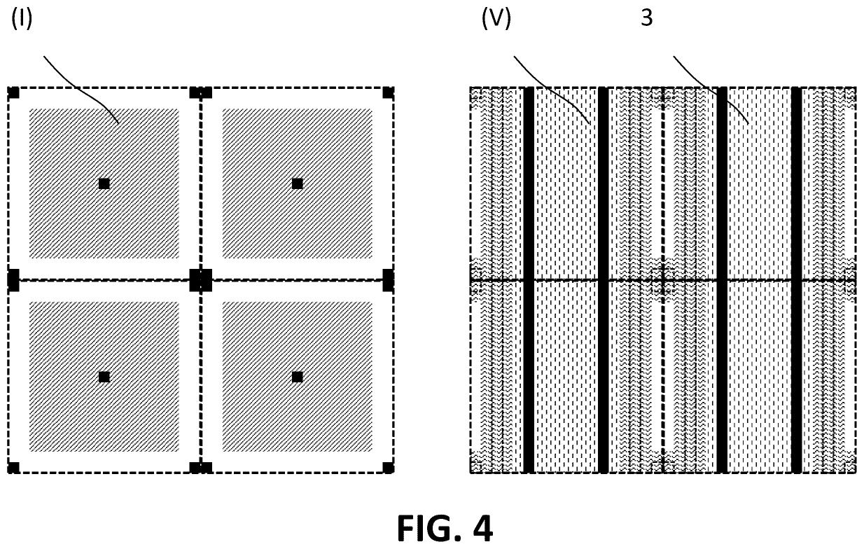

In some embodiments, the openings in the various layers have a particular relative arrangement. This will be explained next by referring to FIGS. 3 and 4. FIG. 3 illustrates various layers of a unit cell for making the capacitor assembly of FIG. 1 in top view and FIG. 4 illustrates how multiple unit cells can be combined for forming a capacitor assembly. In FIG. 3, the captions indicated in between parentheses ‘( )’ indicate a particular layer order.

In FIG. 3, (I) indicates, for a unit cell, structures formed in Polysilicon layer P. Furthermore, vias V1 and V2 are indicated by black rectangles. FIG. 3, (II), indicates a large metal pad formed in metal layer M1. Similarly, patches in metal layer M1 are formed that are electrically connected to vias V2 but which do not connect to the larger metal pad in the center. As can be seen, an opening M1o exists between the patches in metal layer M1 and the larger pad in the center. Opening M1o is sufficient for meeting the design rules concerning metal layer M1. The smaller dashed rectangle in the center corresponds to via V1 and indicates that this via is connected to the center pad and extends downward from that layer.

FIG. 3, (III), indicates a ground plane M2 that is connected using vias V3 to the second electrode of the MIMCAP, T2MIM, which is formed in metal layer M3. As can be seen, vias V2 extend though ground plane M2. In the center, ground plane M2 has an opening M20 for compliance with the design rules. In FIG. 3, (III), vias V3 are not directly arranged underneath CTM layer to comply with design rules.

FIG. 3, (IV), illustrates metal layer M3. Openings M30 are arranged at the edge of the unit cell. As shown in FIG. 3, (III+IV), openings M30 in metal layer M3 are laterally separated from openings M2o in ground plane M2. As both ground plane M2 and second electrode T2MIM formed in metal layer M3 are electrically grounded during operation, no path exists between first electrode T1MIM, which is formed in and/or connected to layers M4 and M5, and first electrode T1HD, which is formed in and/or connected to layers P and M1, that does not cross a grounded metal layer. This is indicated in FIG. 1, which shows two paths from metal layer M4 to metal layer M1 that intersect a grounded layer at the position of the crosses. Consequently, electromagnetic coupling between the MIMCAP and the DTC is prevented and/or limited.

FIG. 3, (V), illustrates the CTM layer. This layer forms the first terminal, T1MIM, of the MIMCAP. The first terminal is formed as a plurality of stripes, wherein each unit cell of capacitor assembly 1 defines a part of a single stripe. The stripe is connected using a via V4 to metal layer M4. A remainder of the CTM layer, i.e. outside the stripe part, forms an opening CTMo. It is noted that FIG. 3, (V), also indicates metal layer M3.

FIG. 3, (VI), illustrates metal layer M4, which comprises, in a center region, openings M40 and which is connected, as shown in FIG. 4 (VII), to metal layer M5 using vias V5. It is noted that vias V4 and V5 can be formed as a single via extending through dielectric layers D4 and D5. Openings M50 in metal layer M5 are aligned with openings CTMo and M30, and openings M40 are aligned with the stripe in the CTM layer, and therefore also with opening M20.

FIG. 4 illustrates, at least for layers P, M3, and CTM, corresponding to FIGS. 3 (I), (V), how the unit cells can be combined for forming capacitor assembly 1. From these figures, it becomes clear that first terminal TIMIM comprises a plurality of parallel stripes.

FIG. 5 illustrates an amplifier 100 comprising the capacitor assembly of the present disclosure. Amplifier 100 comprises an LDMOS transistor Q1 of which a signal to be amplified is received at the gate. The output of Q1 is connected using an inductor L3, which is typically at least partially formed by bondwires, to an output of amplifier 100. In FIG. 5, the output of amplifier 100 is connected to a load impedance Zload. In addition, biasing signals are fed to Q1 through a feed inductor Lfeed.

The output of Q1 is connected to ground via a shunt network 101. This network comprises an inductor L1 arranged in series with a capacitor C1. This latter capacitor is formed using the MIMCAP of capacitor assembly 1 of FIGS. 1-3. First terminal TIMIM is connected through a conductor L2 to a terminal of capacitor C2. This latter capacitor is formed using the DTC of capacitor assembly 1 of FIGS. 1-3. The second terminals of C1 and C2 are electrically grounded.

Capacitor C1 has a capacitance in the range between 0.1 and 10 pF, whereas capacitor C2 has a capacitance in the range between 5 and 500 nF. Typically, the inductance of L2 is large enough so that the resonance frequency of L2 and C2 is much lower than an operational frequency of amplifier 100, which typically lies in the range between 0.1 and 50 GHz. Furthermore, the operational frequency is much larger than resonance frequency of L1 with the parallel combination of C1 and L2. Consequently, Q1 effectively sees, at the operational frequency, a series inductor L3, and a shunt inductor of which the inductance is substantially equal to L1. This latter inductance is typically chosen so that it resonates, at or close to the operational frequency, with output capacitance Cds. In this manner, the negative impact of the output capacitance on the achievable impedance match can be mitigated.

In the above, example embodiments have been explained. However, the present disclosure is not limited to these embodiments. Rather, various modifications are possible without departing from the scope of the disclosure, which is defined by the appended claims and their equivalents.

What is claimed is:

1. A capacitor assembly comprising a vertical stacking of a first capacitor and a second capacitor on a substrate,
wherein the first capacitor comprises a first terminal and a second terminal, wherein the second terminal is formed by a first conductive layer that comprises stress relief openings,
wherein the second capacitor comprises a first terminal and a second terminal,
wherein, relative to a surface of the substrate, the second terminal of the first capacitor lies below the first terminal of the first capacitor, and wherein the second terminal of the second capacitor lies below the first terminal of the second capacitor, and wherein the second capacitor lies below the first capacitor,
wherein the capacitor assembly further comprises a ground layer arranged in between the first conductive layer and the first terminal of the second capacitor, wherein the second terminal of the second capacitor is electrically connected, through one or more vias, to the ground layer and to the first conductive layer, wherein the ground layer comprises stress relief openings that are laterally separated from the stress relief openings of the first conductive layer, and
wherein the ground layer is configured to be electrically grounded during operation.

2. The capacitor assembly according to claim 1, wherein the first terminal of the first capacitor is formed by a capacitor top metal layer, wherein the capacitor top metal layer comprises stress relief openings, wherein the stress relief openings in the ground layer are laterally separated from the stress relief openings of the capacitor top metal layer.

3. The capacitor assembly according to claim 2, wherein the capacitor top metal layer comprises a plurality of stripes that are arranged in parallel and that are laterally separated by the stress relief openings of the capacitor top metal layer.

4. The capacitor assembly according to claim 3, wherein the stress relief openings in the ground layer are arranged underneath the stripes.

5. The capacitor assembly according to claim 2, further comprising a second conductive layer separated from the capacitor top metal layer by a dielectric layer, wherein the second conductive layer is electrically connected to the capacitor top metal layer through one or more vias through the dielectric layer, and wherein the second conductive layer comprises stress relief openings that are laterally separated from the stress relief openings in the capacitor top metal layer.

6. The capacitor assembly according to claim 5, wherein the capacitor assembly comprises a plurality of identical and adjacently arranged unit cells, each unit cell comprising a first capacitor unit cell, a second capacitor unit cell, and a ground plane segment, and wherein the stress relief openings of the second conductive layer are each arranged in a center position of a respective first capacitor unit cell.

7. The capacitor assembly according to claim 5, further comprising a third conductive layer separated from the second conductive layer by a dielectric layer, wherein the third conductive layer is electrically connected to the second conductive layer through one or more vias through the dielectric layer, and wherein the third conductive layer comprises stress relief openings that are laterally aligned with the stress relief openings in the first conductive layer.

8. The capacitor assembly according to claim 7, wherein the capacitor assembly comprises a plurality of identical and adjacently arranged unit cells, each unit cell comprising a first capacitor unit cell, a second capacitor unit cell, and a ground plane segment, and wherein the stress relief openings of the third conductive layer are each arranged at a respective edge of a respective first capacitor unit cell.

9. The capacitor assembly according to claim 7, further comprising a fourth conductive layer separated from the ground layer by a dielectric layer and electrically connected to and/or forming the first terminal of the second capacitor, wherein the fourth conductive layer comprises stress relief openings that are laterally separated from the stress relief openings in the ground layer.

10. The capacitor assembly according to claim 9, wherein the first terminal of the second capacitor is formed by a fifth conductive layer that is separated from the fourth conductive layer by a dielectric layer, and wherein the fourth conductive layer is electrically connected to the fifth conductive layer through one or more vias through the dielectric layer.

11. The capacitor assembly according to claim 10, wherein the first conductive layer, the second conductive layer, the third conductive layer, the fourth conductive layer, the ground layer, and the capacitor top metal layer each comprise one or more metals, and/or wherein the fifth conductive layer comprises a polysilicon layer.

12. The capacitor assembly according to claim 10, wherein the substrate is a semiconductor substrate, wherein the first capacitor is a metal-insulator-metal capacitor, and/or wherein the second capacitor is a high-density capacitor.

13. The capacitor assembly according to claim 12, wherein the second capacitor is a deep trench capacitor comprising a plurality of trenches in the semiconductor substrate of which an inner wall is covered by a first insulating layer, wherein the fifth conductive layer covers the first insulating layer, wherein the semiconductor substrate comprises one or more doped regions that form the second terminal of the second capacitor, and wherein the metal-insulator-metal capacitor comprises a second insulating layer arranged in between the capacitor top metal layer and the first conductive layer.

14. An amplifier, comprising:
a field-effect transistor (FET) having an output capacitance;
the capacitor assembly according to claim 12; and
a shunt network connected to a drain of the FET and comprising a series connection of a first inductor and the first capacitor of the capacitor assembly, wherein the first inductor is connected to the drain of the FET, and wherein the first terminal of the first capacitor of the capacitor assembly is connected to the first inductor,
wherein the shunt network further comprises the second capacitor of the capacitor assembly connected in series with a second inductor, wherein the second inductor is connected in between the first terminal of the first capacitor of the capacitor assembly and the second capacitor of the capacitor assembly, and wherein the second capacitor of the capacitor assembly has its first terminal connected to the second inductor.

15. The amplifier according to claim 14, wherein the FET comprises a laterally diffused metal-oxide-semiconductor transistor.

16. The amplifier according to claim 15, wherein the second capacitor is a deep trench capacitor comprising a plurality of trenches in the semiconductor substrate of which an inner wall is covered by a first insulating layer, wherein the fifth conductive layer covers the first insulating layer, wherein the semiconductor substrate comprises one or more doped regions that form the second terminal of the second capacitor, and wherein the insulating layer of the deep trench capacitor is formed by a gate oxide layer of the laterally diffused metal-oxide semiconductor transistor.

17. The capacitor assembly according to claim 1, wherein the capacitor assembly comprises a plurality of identical and adjacently arranged unit cells, each unit cell comprising a first capacitor unit cell, a second capacitor unit cell, and a ground plane segment.

18. The capacitor assembly according to claim 17, wherein the stress relief openings of the ground plane are each arranged in a respective center region of a unit cell among the plurality of unit cells.

19. The capacitor assembly according to claim 17, wherein the stress relief openings of the first conductive layer are each arranged at a respective edge of a respective first capacitor unit cell.

20. The capacitor assembly according to claim 1, further comprising a fourth conductive layer separated from the ground layer by a dielectric layer and electrically connected to and/or forming the first terminal of the second capacitor, wherein the fourth conductive layer comprises stress relief openings that are laterally separated from the stress relief openings in the ground layer, wherein the capacitor assembly comprises a plurality of identical and adjacently arranged unit cells, each unit cell comprising a first capacitor unit cell, a second capacitor unit cell, and a ground plane segment, and wherein the stress relief openings of the fourth conductive layer are each arranged at a respective corner of a respective second capacitor unit cell.
